(19) United States
(12) Patent Application Publication
(10) Pub. No.: US 2026/0146317 A1
(43) Pub. Date: May 28, 2026

(54) DEPOSITION APPARATUS AND ELECTRONIC DEVICE INCLUDING DISPLAY PANEL MANUFACTURED BY SHADOW MASK OF THE DEPOSITION APPARATUS

(71) Applicant: Samsung Display Co., LTD., Yongin-si (KR)

(72) Inventors: JINYONG LEE, Yongin-si (KR); SUNGRAG MA, Yongin-si (KR)

(21) Appl. No.: 19/382,652

(22) Filed: Nov. 7, 2025

(30) Foreign Application Priority Data
Nov. 27, 2024 (KR) 10-2024-0171934

(51) Int. Cl. C23C 16/04; C23C 16/458

(52) U.S. Cl. CPC C23C 16/042; C23C 16/4586

(57) ABSTRACT

Disclosed is a deposition apparatus which includes a first electrostatic chuck having an opening defined therein and including a plurality of first electrodes, a second electrostatic chuck that is disposed over the first electrostatic chuck and that includes a lower surface to which a substrate is attracted, and a shadow mask that is disposed between the first electrostatic chuck and the second electrostatic chuck and that includes a mask attracted to an upper surface of the first electrostatic chuck and a plurality of conductive patterns disposed on the mask. The plurality of conductive patterns overlap the plurality of first electrodes when viewed on a plane.

This application claims priority to Korean Patent Application No. 10-2024-0171934, filed on Nov. 27, 2024, and all the benefits accruing therefrom under 35 U.S.C. § 119, the content of which in its entirety is herein incorporated by reference.

### BACKGROUND

### Field

Embodiments of the present disclosure described herein relate to a deposition apparatus and an electronic device including a display panel manufactured by a shadow mask of the deposition apparatus.

### Description of the Related Art

In general, electronic devices, such as a smart phone, a digital camera, a notebook computer, a car navigation device, and a smart television, which provide an image to a user include a display device for displaying an image. The display device generates an image and provides the generated image to the user through a display screen.

The display device includes a display panel including a plurality of pixels that generate an image. Each of the pixels includes a light emitting element and a plurality of transistors connected to the light emitting element. The light emitting element is driven by the transistors to generate light.

The light emitting element includes an anode, a cathode, and an emissive layer disposed between the anode and the cathode. Holes and electrons are injected into the emissive layer from the anode and the cathode, respectively, to form excitons, and the light emitting element emits light as the excitons transition to a ground state. When the light emitting elements of the pixels are manufactured, a shadow mask is disposed on a substrate, and an organic material for forming the emissive layers is provided on the substrate through openings of the shadow mask.

After the shadow mask is aligned with the substrate, a deposition process for depositing the organic material on the substrate is performed. The substrate and the shadow mask are attracted and clamped to electrostatic chucks. In an example in which the attraction force of the electrostatic chuck for the shadow mask is weak, the shadow mask may not be normally clamped to the electrostatic chuck. In this case, the shadow mask may not be normally aligned with the substrate. Accordingly, a technology for more firmly clamping a shadow mask to an electrostatic chuck is desired.

### SUMMARY

Embodiments of the present disclosure provide a deposition apparatus for more firmly clamping a shadow mask to an electrostatic chuck and an electronic device including a display panel manufactured by the shadow mask of the deposition apparatus.

According to an embodiment, a deposition apparatus includes a first electrostatic chuck in which an opening is defined and including a plurality of first electrodes, a second electrostatic chuck that is disposed over the first electrostatic chuck and that includes a lower surface to which a substrate is attracted, and a shadow mask that is disposed between the first electrostatic chuck and the second electrostatic chuck and that includes a mask attracted to an upper surface of the first electrostatic chuck and a plurality of conductive patterns disposed on the mask, and the plurality of conductive patterns overlap the plurality of first electrodes when viewed on a plane.

According to an embodiment, a deposition apparatus includes a first electrostatic chuck in which an opening is defined and including a plurality of first electrodes, a second electrostatic chuck that is disposed over the first electrostatic chuck and that includes a lower surface to which a substrate is attracted, and a shadow mask disposed between the first electrostatic chuck and the second electrostatic chuck. The shadow mask includes a mask attracted to an upper surface of the first electrostatic chuck, a plurality of conductive patterns disposed on the mask, and a plurality of mask alignment keys disposed on the mask, and the plurality of mask alignment keys are disposed inward of the plurality of conductive patterns when viewed on a plane.

According to an embodiment, an electronic device includes a display device, an electro-optical module that is disposed under the display device and that receives an optical signal through a first transmissive area of the display device, and a casing that accommodates the display device and the electro-optical module. The display device includes a display panel in which the first transmissive area is defined and a window disposed on the display panel, and the display panel is manufactured by a shadow mask. The shadow mask includes a mask in which a plurality of mask openings are defined, a plurality of conductive patterns disposed on the mask, and a plurality of mask alignment keys disposed inward of the plurality of conductive patterns on the mask.

### BRIEF DESCRIPTION OF THE DRAWINGS

The above and other objects and features of the present disclosure will become apparent by describing in detail embodiments thereof with reference to the accompanying drawings.

FIG. 1 is an exploded perspective view of a deposition apparatus according to an embodiment of the present disclosure.

FIG. 2 is an enlarged view of a mother substrate illustrating a planar configuration of the mother substrate illustrated in FIG. 1.

FIG. 3 is an enlarged view of a shadow mask illustrating a planar configuration of the shadow mask illustrated in FIG. 2.

FIG. 4 is an exploded perspective view of an electronic device including a display panel manufactured through the shadow mask of the deposition apparatus illustrated in FIG. 1.

FIG. 5 is a block diagram of the electronic device illustrated in FIG. 4.

FIG. 6 is a plan view of the display panel illustrated in FIG. 4.

FIG. 7 is a view illustrating a cross-section of one pixel illustrated in FIG. 6.

FIG. 8 is a sectional view taken along line I-I′ illustrated in FIG. 3.

FIG. 9 is a sectional view taken along line II-II′ illustrated in FIG. 3.

FIGS. 10A to 10C are views for explaining a deposition process of the deposition apparatus.

FIG. 11 is a view illustrating a state in which a deposition material is provided on the mother substrate in FIG. 10C.

FIG. 12 is a view illustrating a configuration of a comparative shadow mask according to a comparative example.

FIGS. 13A and 13B are views obtained by measuring movement states of mask alignment keys when the comparative shadow mask is used in a deposition process.

FIGS. 14A and 14B are views obtained by measuring movement states of mask alignment keys when a shadow mask according to an embodiment of the present disclosure is used in a deposition process.

### DETAILED DESCRIPTION

In this specification, when a component (or, an area, a layer, a part, or the like) is referred to as being “on”, “connected to” or “coupled to” another component, this means that the component may be directly on, connected to, or coupled to the other component or a third component may be present therebetween.

Identical reference numerals refer to identical components. In the drawings, the thicknesses, proportions, and dimensions of components are exaggerated for effective description.

As used herein, the term “and/or” includes all of one or more combinations defined by related components.

Terms such as first, second, and the like may be used to describe various components, but the components should not be limited by the terms. The terms as used herein may distinguish one component from other components. For example, without departing the scope of the present disclosure, a first component may be referred to as a second component, and similarly, the second component may also be referred to as the first component. The terms of a singular form may include plural forms unless otherwise specified.

Terms such as “below”, “under”, “above”, and “over” are used to describe a relationship between components illustrated in the drawings. The terms are relative concepts and are described based on directions illustrated in the drawing.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

Unless otherwise defined, all terms used herein, including technical or scientific terms, have the same meanings as those generally understood by those skilled in the art to which the present disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the present application.

It should be understood that terms such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

Hereinafter, embodiments of the present disclosure will be described with reference to the accompanying drawings.

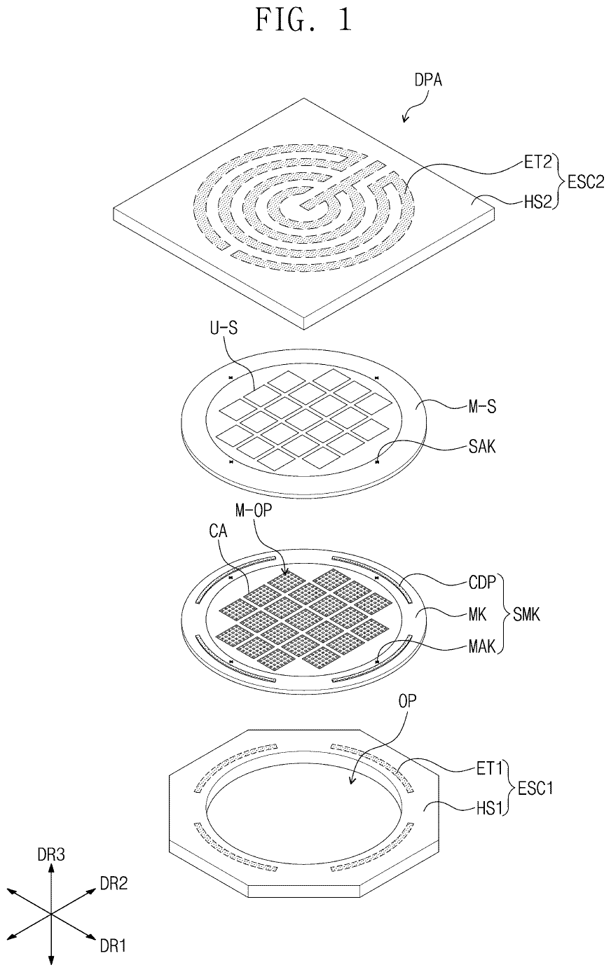

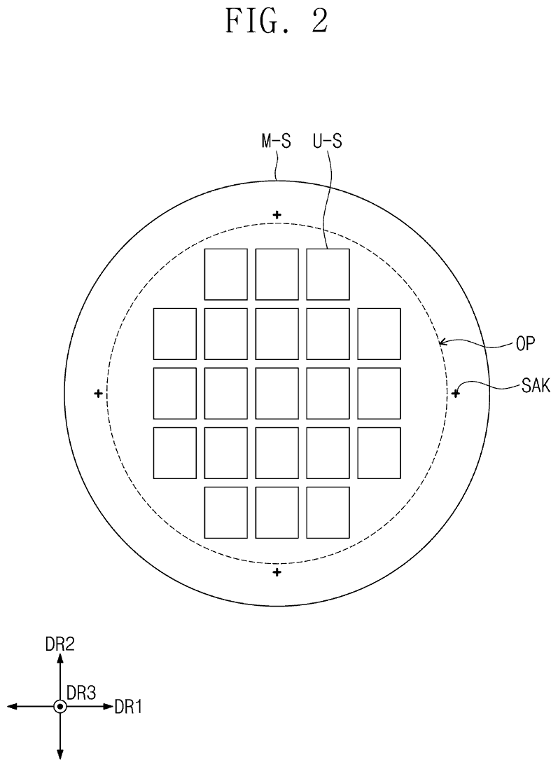

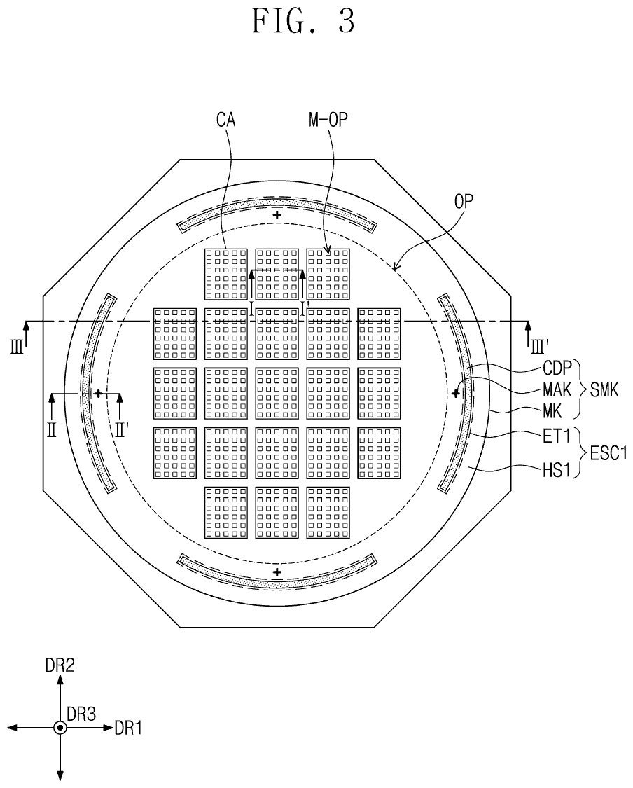

FIG. 1 is an exploded perspective view of a deposition apparatus according to an embodiment of the present disclosure. FIG. 2 is an enlarged view of a mother substrate illustrating a planar configuration of the mother substrate illustrated in FIG. 1. FIG. 3 is an enlarged view of a shadow mask illustrating a planar configuration of the shadow mask illustrated in FIG. 2.

For example, in FIG. 1, the mother substrate M-S, which is an object to be processed, is illustrated together with the deposition apparatus DPA. In FIG. 2, an opening OP is illustrated together with the mother substrate M-S, and in FIG. 3, the shadow mask SMK is illustrated together with a first electrostatic chuck ESC1.

Referring to FIG. 1, the deposition apparatus DPA may include the first electrostatic chuck ESC1, a second electrostatic chuck ESC2, and the shadow mask SMK. In this specification, a plane is defined by a first direction DR1 and a second direction DR2 that cross each other at a right angle, and a direction perpendicular to the plane is defined as a third direction DR3. The first electrostatic chuck ESC1, the second electrostatic chuck ESC2, and the shadow mask SMK are arranged in the third direction DR3.

Hereinafter, the expression “when viewed from above the plane” used herein means that it is viewed in the third direction DR3. The term “overlap” used herein refers to a state in which components overlap each other when viewed from above the plane.

The second electrostatic chuck ESC2 may be disposed over the first electrostatic chuck ESC1. The shadow mask SMK may be disposed between the first electrostatic chuck ESC1 and the second electrostatic chuck ESC2. The mother substrate M-S, which is an object to be processed, may be disposed between the shadow mask SMK and the second electrostatic chuck ESC2.

The first electrostatic chuck ESC1 may have a frame shape (or, a ring shape). To have the frame shape, the opening OP formed through the first electrostatic chuck ESC1 in the third direction DR3 may be defined in the first electrostatic chuck ESC1.

For example, the opening OP may have a circular shape when viewed from above the plane. However, the shape of the opening OP is not limited thereto. For example, the periphery of the first electrostatic chuck ESC1 may have an octagonal shape. However, the shape of the periphery of the first electrostatic chuck ESC1 is not limited thereto.

The first electrostatic chuck ESC1 may include a first housing HS1 and a plurality of first electrodes ET1 disposed inside the first housing HS1. For example, in FIG. 1, the first electrodes ET1 disposed inside the first housing HS1 are illustrated in gray by dotted lines.

The first housing HS1 may substantially define the exterior of the first electrostatic chuck ESC1. Accordingly, to have a frame shape, the circular opening OP may be defined in the first housing HS1.

The first electrodes ET1 may be disposed along the periphery of the first housing HS1. Accordingly, the first electrodes ET1 may be disposed to surround the opening OP.

For example, the first electrodes ET1 may extend in a curved shape in correspondence to the circular periphery of the opening OP. However, the shape of the first electrodes ET1 is not limited thereto. The first electrodes ET1 may include positive electrodes and negative electrodes. A positive voltage may be applied to the positive electrodes, and a negative voltage may be applied to the negative electrodes.

Although not illustrated, the first electrodes ET1 may be connected to a power supply through wiring. The power supply may apply the positive voltage and the negative voltage to the first electrodes ET1. In an example in which the positive voltage and the negative voltage are applied to the first electrodes ET1, an electrostatic force may be generated. The shadow mask SMK may be attracted and clamped to (i.e., fixed to) the first electrostatic chuck ESC1 by the electrostatic force. A structure in which an object is fixed by an electrostatic force generated by an electrostatic chuck is obvious to those skilled in the art, and therefore detailed description thereof will be omitted.

The second electrostatic chuck ESC2 may have a flat plate shape defined by the first direction DR1 and the second direction DR2. The second electrostatic chuck ESC2 may have a rectangular shape when viewed from above the plane. However, the shape of the second electrostatic chuck ESC2 is not limited thereto. The second electrostatic chuck ESC2 may overlap the first electrostatic chuck ESC1 when viewed from above the plane.

The second electrostatic chuck ESC2 may include a second housing HS2 and a plurality of second electrodes ET2 disposed inside the second housing HS2. For example, in FIG. 1, the second electrodes ET2 disposed inside the second housing HS2 are illustrated in gray by dotted lines.

The second housing HS2 may substantially define the exterior of the second electrostatic chuck ESC2. Accordingly, the second housing HS2 may have a flat plate shape defined by the first direction DR1 and the second direction DR2 and may have a rectangular shape when viewed from above the plane.

The second electrodes ET2 may extend in a shape obtained by a combination of curved and linear shapes and may have various shapes without being limited to the shape illustrated in FIG. 1. When viewed from above the plane, the second electrodes ET2 may be disposed such that the second electrodes ET2 overlap the mother substrate M-S.

The second electrodes ET2 may include positive electrodes and negative electrodes. A positive voltage may be applied to the positive electrodes, and a negative voltage may be applied to the negative electrodes. Although not illustrated, the second electrodes ET2 may be connected to a power supply through wiring. The power supply may apply the positive voltage and the negative voltage to the second electrodes ET2.

When the positive voltage and the negative voltage are applied to the second electrodes ET2, an electrostatic force may be generated. The mother substrate M-S may be attracted and clamped to the second electrostatic chuck ESC2 by the electrostatic force.

Referring to FIGS. 1 and 2, the mother substrate M-S may have a circular shape when viewed from above the plane. However, the shape of the mother substrate M-S is not limited thereto. The mother substrate M-S may be defined as a wafer. The mother substrate M-S may be formed of various materials such as, for example, a silicon substrate or a glass substrate.

The mother substrate M-S may include a plurality of unit substrates U-S. The unit substrates U-S may overlap the opening OP when viewed from above the plane. That is, the unit substrates U-S may be disposed in the opening OP when viewed from above the plane.

The unit substrates U-S may be arranged in the first direction DR1 and the second direction DR2. The unit substrates U-S may extend longer in the second direction DR2 than in the first direction DR1. Pixels may be formed on the unit substrates U-S. After the pixels are formed on the unit substrates U-S, the unit substrates U-S may be cut and separated from the mother substrate M-S. A display panel may be manufactured by forming the pixels on the unit substrates U-S.

In an embodiment of the present disclosure, an emissive layer of each of the pixels may be formed by the deposition apparatus DPA. This manufacturing process will be described herein in detail.

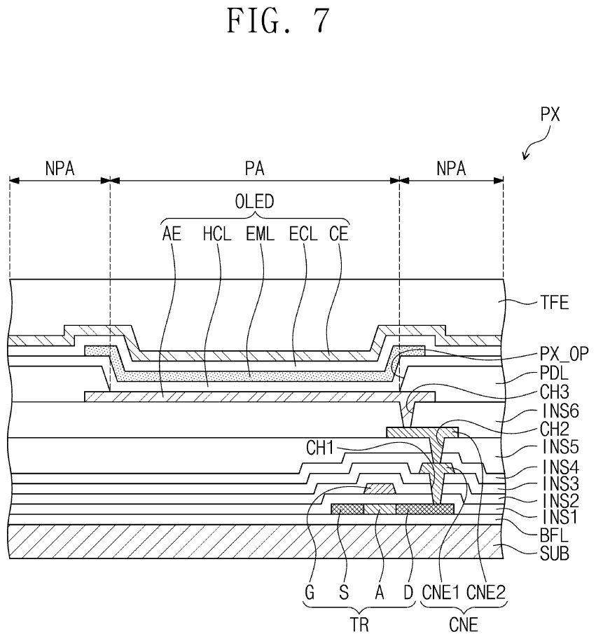

A plurality of substrate alignment keys SAK may be defined on the mother substrate M-S. The substrate alignment keys SAK may be formed by various metal layers on the mother substrate M-S. The metal layers capable of forming the substrate alignment keys SAK will be described in the structure of the pixel illustrated in FIG. 7.

The substrate alignment keys SAK may be disposed such that the substrate alignment keys SAK do not overlap the opening OP when viewed from above the plane. The substrate alignment keys SAK may have various shapes. For example, as illustrated in FIG. 2, the substrate alignment keys SAK may have a cross shape. However, the shape of the substrate alignment keys SAK is not limited thereto.

The substrate alignment keys SAK may be adjacent to the periphery of the mother substrate M-S. For example, four substrate alignment keys SAK may be disposed at four points. For example, the substrate alignment keys SAK may be disposed at 90 degrees, 180 degrees, 270 degrees, and 360 degrees, based on the rotation angle with respect to the center point of the mother substrate M-S.

Two substrate alignment keys SAK may be spaced apart from the center of the mother substrate M-S in the first direction DR1 and may be adjacent to the periphery of the mother substrate M-S. The remaining two substrate alignment keys SAK may be spaced apart from the center of the mother substrate M-S in the second direction DR2 and may be adjacent to the periphery of the mother substrate M-S.

Although the four substrate alignment keys SAK and the positions of the substrate alignment keys SAK have been described with reference to FIG. 2, the number of substrate alignment keys SAK and the positions of the substrate alignment keys SAK are not limited to the configuration illustrated in FIG. 2.

Referring to FIGS. 1 and 3, the shadow mask SMK may have a circular shape. However, the shape of the shadow mask SMK is not limited thereto. The shadow mask SMK may have a flat plate shape defined by the first direction DR1 and the second direction DR2.

The shadow mask SMK may include a mask MK, a plurality of mask alignment keys MAK, and a plurality of conductive patterns CDP.

The mask MK may substantially define the exterior of the shadow mask SMK. Accordingly, the mask MK may have a circular shape. In some aspects, the mask MK may have a flat plate shape defined by the first direction DR1 and the second direction DR2. A plurality of mask openings M-OP may be defined in the mask MK.

A planar area of the mask MK may include a plurality of cell areas CA when viewed from above the plane. The cell areas CA may overlap the opening OP. The cell areas CA may overlap the unit substrates U-S, respectively. The mask openings M-OP may be defined in the cell areas CA, respectively.

The mask alignment keys MAK may be disposed on the mask MK. The mask alignment keys MAK may overlap the substrate alignment keys SAK, respectively, when viewed from above the plane. The mother substrate M-S and the mask MK may be aligned with each other by the substrate alignment keys SAK and the mask alignment keys MAK.

The mask alignment keys MAK may be disposed such that the mask alignment keys MAK do not overlap the opening OP when viewed from above the plane. The shape, number, and positions of the mask alignment keys MAK may correspond to the shape, number, and positions of the substrate alignment keys SAK.

The mask alignment keys MAK may have the same shape as the substrate alignment keys SAK. For example, as illustrated in FIG. 3, the mask alignment keys MAK have a cross shape. However, without being limited thereto, the mask alignment keys MAK may have various shapes depending on the shape of the substrate alignment keys SAK.

The mask alignment keys MAK may be adjacent to the periphery of the mask MK. Likewise to the substrate alignment keys SAK, four mask alignment keys MAK may be disposed at four points. The mask alignment keys MAK may be disposed at 90 degrees, 180 degrees, 270 degrees, and 360 degrees, based on the rotation angle with respect to the center point of the mask MK.

Two mask alignment keys MAK may be spaced apart from the center of the mask MK in the first direction DR1 and may be adjacent to the periphery of the mask MK. The remaining two mask alignment keys MAK may be spaced apart from the center of the mask MK in the second direction DR2 and may be adjacent to the periphery of the mask MK.

The conductive patterns CDP may be disposed on the mask MK. The conductive patterns CDP may overlap the first electrodes ET1, respectively, when viewed from above the plane. The conductive patterns CDP may be disposed such that the conductive patterns CDP do not overlap the opening OP when viewed from above the plane. The conductive patterns CDP may extend in a curved shape to correspond to the shape of the first electrodes ET1. The conductive patterns CDP may be adjacent to the periphery of the mask MK.

The conductive pattern CDP may include a paramagnetic material. For example, the conductive patterns CDP may include tungsten, aluminum, or magnesium.

The mask alignment keys MAK may be disposed inward of the conductive patterns CDP. For example, when viewed from above the plane, the mask alignment keys MAK may be closer to the opening OP than the conductive patterns CDP. In some aspects, when viewed from above the plane, the conductive patterns CDP may be closer to the periphery of the mask MK than the mask alignment keys MAK.

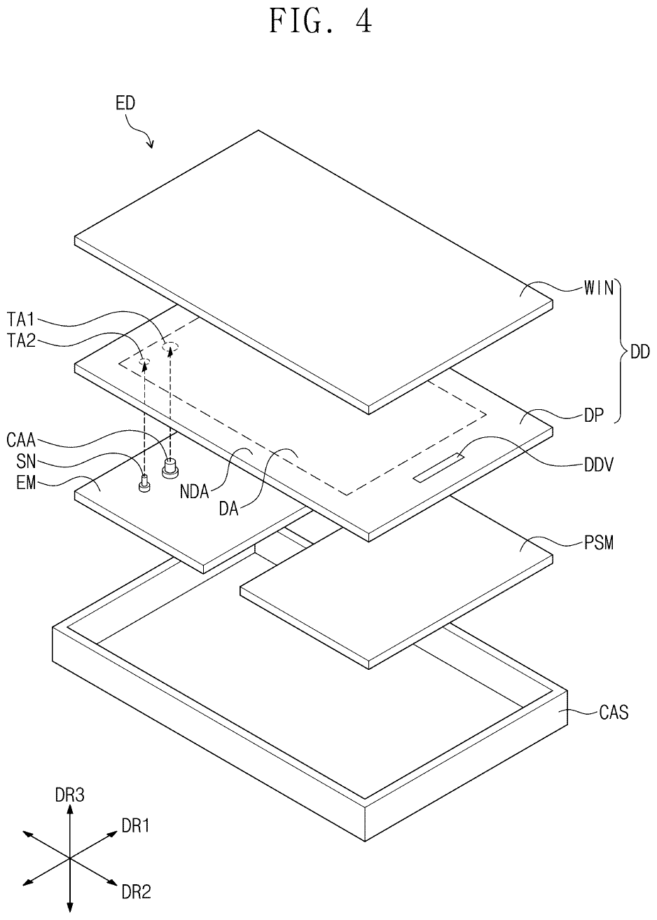

FIG. 4 is an exploded perspective view of an electronic device including a display panel manufactured through the shadow mask of the deposition apparatus illustrated in FIG. 1.

Referring to FIG. 4, the electronic device ED may include a display device DD, a camera CAA, a sensor SN, an electronic module EM, a power supply module PSM, and a casing CAS.

The display device DD may include a window WIN and the display panel DP. The window WIN and the display panel DP may each have a rectangular shape with short sides extending in the first direction DR1 and long sides extending in the second direction DR2.

The window WIN may be disposed on the display panel DP and may protect the display panel DP. The window WIN may transmit an image generated by the display module DM and may provide the image to a user.

The display panel DP may include a display area DA that displays an image and a non-display area NDA disposed around the display area DA. The display panel DP may include a plurality of pixels that are disposed in the display area DA and that display an image. The configuration of the pixels will be described herein in detail.

A first transmissive area TA1 and a second transmissive area TA2 may be defined in the display panel DP. The first transmissive area TA1 and the second transmissive area TA2 may be defined in the display area DA. In the display area DA, the first transmissive area TA1 and the second transmissive area TA2 may have a higher light transmittance than the surrounding area.

The camera CAA may be disposed under the first transmissive area TA1, and the sensor SN may be disposed under the second transmissive area TA2. Light passing through the first transmissive area TA1 and the second transmissive area TA2 may be provided to the camera CAA and the sensor SN.

The display device DD may include a data driver DDV disposed on the non-display area NDA of the display panel DP. The data driver DDV may be manufactured in the form of an integrated circuit chip and may be mounted on the non-display area NDA. However, without being limited thereto, the data driver DDV may be mounted on a flexible circuit board connected to the display panel DP.

The electronic module EM and the power supply module PSM may be disposed under the display panel DP. Although not illustrated, the electronic module EM and the power supply module PSM may be connected with each other through a separate flexible circuit board. The electronic module EM may control an operation of the display device DD. The power supply module PSM may supply power to the electronic module EM.

The casing CAS may accommodate the display device DD, the electronic module EM, and the power supply module PSM. The casing CAS may protect the display device DD, the electronic module EM, and the power supply module PSM.

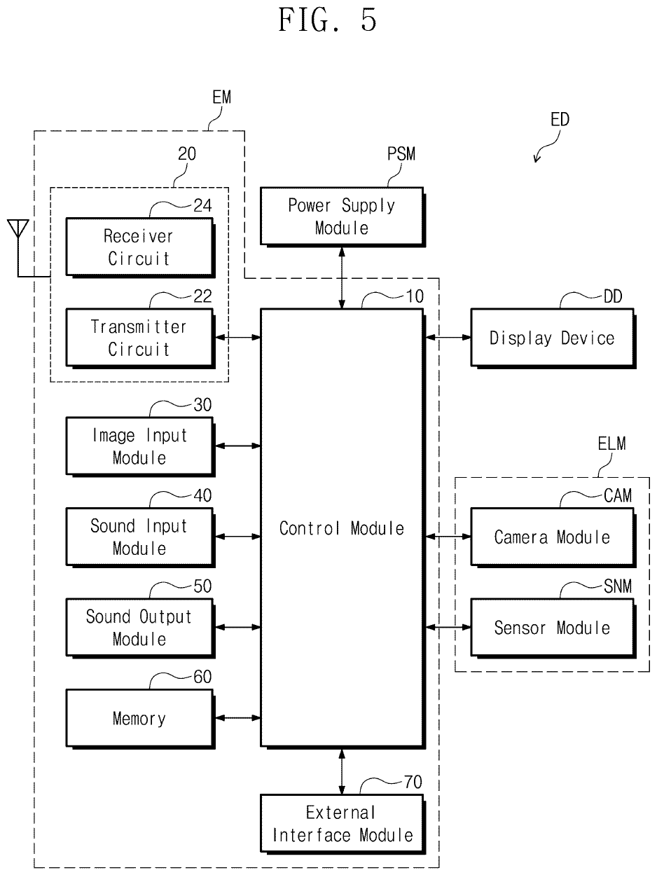

FIG. 5 is a block diagram of the electronic device illustrated in FIG. 4.

Referring to FIG. 5, the electronic device ED may include the electronic module EM, the power supply module PSM, the display device DD, and an electro-optical module ELM. The electronic module EM may include a control module 10, a wireless communication module 20, an image input module 30, a sound input module 40, a sound output module 50, a memory 60, and an external interface module 70. The modules may be mounted on a circuit board or may be electrically connected through a flexible circuit board. The electronic module EM may be electrically connected with the power supply module PSM.

The control module 10 may control overall operation of the electronic device ED. For example, the control module 10 may activate or deactivate the display device DD in response to a user input. The control module 10 may control the image input module 30, the sound input module 40, and the sound output module 50 in response to a user input. The control module 10 may include at least one microprocessor.

The wireless communication module 20 may transmit/receive wireless signals with another terminal using Bluetooth or Wi-Fi. The wireless communication module 20 may transmit/receive sound signals using a general communication line. The wireless communication module 20 may include a transmitter circuit 22 that modulates a signal to be transmitted and transmits the modulated signal and a receiver circuit 24 that demodulates a received signal.

The image input module 30 may process an image signal to convert the image signal into image data capable of being displayed on the display device DD. The sound input module 40 may receive an external sound signal through a microphone in a voice recording mode or a voice recognition mode and may convert the external sound signal into electrical voice data. The sound output module 50 may convert sound data received from the wireless communication module 20 or sound data stored in the memory 60 and may output the converted sound data to the outside.

The external interface module 70 may serve as an interface connected to an external charger, a wired/wireless data port, and a card socket (e.g., a memory card or a SIM/UIM card).

The power supply module PSM may supply power required for overall operation of the electronic device ED. The power supply module PSM may include a conventional battery device.

The electro-optical module ELM may be an electronic part that outputs or receives an optical signal. The electro-optical module ELM may transmit or receive an optical signal through a partial area of the display device DD.

In an embodiment of the present disclosure, the electro-optical module ELM may include a camera module CAM and a sensor module SNM. The camera module CAM may include the camera CAA illustrated in FIG. 4. The sensor module SNM may include the sensor SN illustrated in FIG. 4. Accordingly, the electro-optical module EML may include the camera CAA and the sensor SN and may be disposed under the display device DD illustrated in FIG. 4.

The electro-optical module EML may receive an optical signal (e.g., an external image) through the first transmissive area TA1. The electro-optical module EML may transmit and receive optical signals (e.g., transmission/reception signals for proximity sensing) through the second transmissive area TA2. The electro-optical module ELM may be disposed in the electronic module EM. Alternatively, the electro-optical module ELM may be manufactured as a separate module and may be accommodated in the above-described casing CAS.

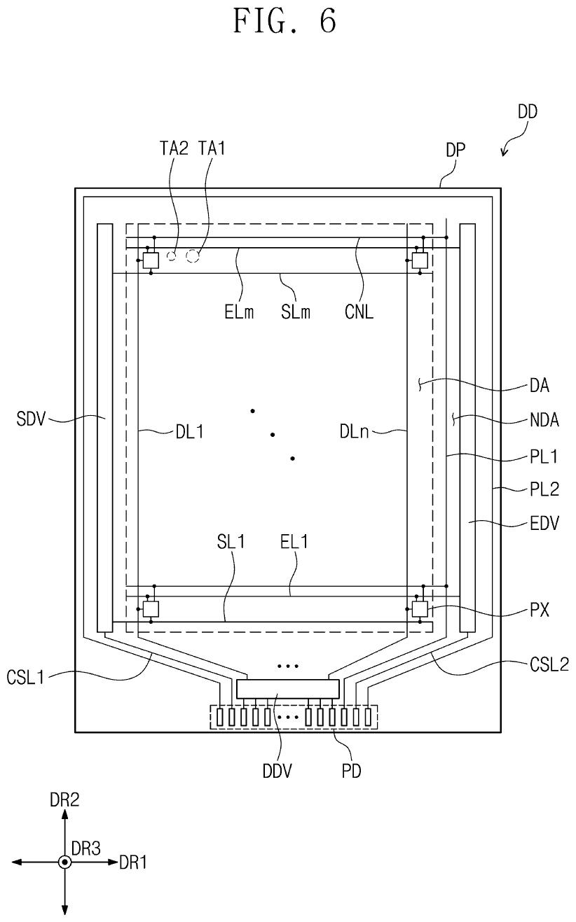

FIG. 6 is a plan view of the display panel illustrated in FIG. 4.

Referring to FIG. 6, the display device DD may include the display panel DP, a scan driver SDV, the data driver DDV, a light emission driver EDV, and a plurality of pads PD.

The display panel DP may include the display area DA and the non-display area NDA surrounding the display area DA. The display panel DP may include a plurality of pixels PX, a plurality of scan lines SL1 to SLm, a plurality of data lines DL1 to DLn, a plurality of light emission lines EL1 to ELm, a first control line CSL1, a second control line CSL2, a first power line PL1, a second power line PL2, and connecting lines CNL. “m” and “n” are natural numbers.

The pixels PX may be disposed in the display area DA. The scan driver SDV and the light emission driver EDV may be disposed in the non-display areas NDA adjacent to the long sides of the display panel DP, respectively. The data driver DDV may be disposed in the non-display area NDA adjacent to one of the short sides of the display panel DP. The data driver DDV may be adjacent to the lower end of the display panel DP when viewed from above the plane.

The scan lines SL1 to SLm may extend in the first direction DR1 and may be connected to the pixels PX and the scan driver SDV. The data lines DL1 to DLn may extend in the second direction DR2 and may be connected to the pixels PX and the data driver DDV. The light emission lines EL1 to ELm may extend in the first direction DR1 and may be connected to the pixels PX and the light emission driver EDV.

The first power line PL1 may extend in the second direction DR2 and may be disposed in the non-display area NDA. The first power line PL1 may be disposed between the display area DA and the light emission driver EDV.

The connecting lines CNL may extend in the first direction DR1 and may be arranged in the second direction DR2. The connecting lines CNL may be connected to the first power line PL1 and the pixels PX. A first voltage may be applied to the pixels PX through the first power line PL1 and the connecting lines CNL connected with each other.

The second power line PL2 may be disposed in the non-display area NDA and may extend along the long sides of the display panel DP and the other short side of the display panel DP where the data driver DDV is not disposed. The second power line PL2 may be disposed outward of the scan driver SDV and the light emission driver EDV.

Although not illustrated, the second power line PL2 may extend toward the display area DA and may be connected to the pixels PX. A second voltage having a lower level than the first voltage may be applied to the pixels PX through the second power line PL2.

The first control line CSL1 may be connected to the scan driver SDV and may extend toward the lower end of the display panel DP. The second control line CSL2 may be connected to the light emission driver EDV and may extend toward the lower end of the display panel DP. The data driver DDV may be disposed between the first control line CSL1 and the second control line CSL2.

The pads PD may be disposed in the non-display area NDA adjacent to the lower end of the display panel DP and may be closer to the lower end of the display panel DP than the data driver DDV. The data driver DDV, the first power line PL1, the second power line PL2, the first control line CSL1, and the second control line CSL2 may be connected to the pads PD. The data lines DL1 to DLn may be connected to the data driver DDV, and the data driver DDV may be connected to the pads PD corresponding to the data lines DL1 to DLn.

Although not illustrated, the display device DD may further include a timing controller for controlling operations of the scan driver SDV, the data driver DDV, and the light emission driver EDV and a voltage generator for generating the first voltage and the second voltage. The timing controller and the voltage generator may be mounted on a printed circuit board and may be connected to the pads PD through the printed circuit board.

The scan driver SDV may generate a plurality of scan signals, and the scan signals may be applied to the pixels PX through the scan lines SL1 to SLm. The data driver DDV may generate a plurality of data voltages, and the data voltages may be applied to the pixels PX through the data lines DL1 to DLn. The light emission driver EDV may generate a plurality of light emission signals, and the light emission signals may be applied to the pixels PX through the light emission lines EL1 to ELm.

The pixels PX may receive the data voltages in response to the scan signals. The pixels PX may display an image by emitting light having luminance corresponding to the data voltages in response to the light emission signals.

FIG. 7 is a view illustrating a cross-section of one pixel illustrated in FIG. 6.

Referring to FIG. 7, the pixel PX may include a transistor TR and a light emitting element OLED connected to the transistor TR. Although one pixel PX is illustrated as an example, a plurality of pixels PX may be substantially disposed on a substrate SUB.

The light emitting element OLED may include a first electrode AE, a second electrode CE, a hole control layer HCL, an electron control layer ECL, and an emissive layer EML. The first electrode AE may be an anode electrode, and the second electrode CE may be a cathode electrode.

The transistor TR and the light emitting element OLED may be disposed on the substrate SUB. The planar area of the substrate SUB may be divided into an emissive portion PA and a non-emissive portion NPA around the emissive portion PA. The light emitting element OLED may be disposed on the emissive portion PA.

The substrate SUB may be formed by the unit substrate U-S of the mother substrate M-S described herein. A buffer layer BFL may be disposed on the substrate SUB. The buffer layer BFL may be an inorganic layer.

A semiconductor pattern S, A, and D may be disposed on the buffer layer BFL. The semiconductor pattern S, A, and D may include poly silicon. However, without being limited thereto, the semiconductor pattern S, A, and D may include amorphous silicon or metal oxide.

The semiconductor pattern S, A, and D may be doped with an N-type dopant or a P-type dopant. The semiconductor pattern S, A, and D may include highly-doped areas and a lightly-doped area. The highly-doped areas may have a higher conductivity than the lightly-doped area and may substantially serve as a source electrode and a drain electrode of the transistor TR. The lightly-doped area may substantially correspond to an active (or, channel) area of the transistor.

The source S, the active area A, and the drain D of the transistor TR may be formed from the semiconductor pattern S, A, and D. A first insulating layer INS1 may be disposed on the semiconductor pattern S, A, and D. A gate electrode G of the transistor TR may be disposed on the first insulating layer INS1. A second insulating layer INS2 may be disposed on the gate electrode G. A third insulating layer INS3 may be disposed on the second insulating layer INS2.

A connecting electrode CNE may be disposed between the transistor TR and the light emitting element OLED and may connect the transistor TR and the light emitting element OLED. The connecting electrode CNE may include a first connecting electrode CNE1 and a second connecting electrode CNE2.

The first connecting electrode CNE1 may be disposed on the third insulating layer INS3 and may be connected to the drain D through a first contact hole CH1 defined in the first to third insulating layers INS1 to INS3. A fourth insulating layer INS4 may be disposed on the first connecting electrode CNE1. A fifth insulating layer INS5 may be disposed on the fourth insulating layer INS4.

The second connecting electrode CNE2 may be disposed on the fifth insulating layer INS5. The second connecting electrode CNE2 may be connected to the first connecting electrode CNE1 through a second contact hole CH2 defined in the fifth insulating layer INS5. A sixth insulating layer INS6 may be disposed on the second connecting electrode CNE2. The first to sixth insulating layers INS1 to INS6 may be inorganic layers or organic layers.

The first electrode AE may be disposed on the sixth insulating layer INS6. The first electrode AE may be connected to the second connecting electrode CNE2 through a third contact hole CH3 defined in the sixth insulating layer INS6. A pixel defining layer PDL exposing a certain portion of the first electrode AE may be disposed on the first electrode AE and the sixth insulating layer INS6. An opening PX_OP for exposing the certain portion of the first electrode AE may be defined in the pixel defining layer PDL.

The hole control layer HCL may be disposed on the first electrode AE and the pixel defining layer PDL. The hole control layer HCL may be commonly disposed on the emissive portion PA and the non-emissive portion NPA. The hole control layer HCL may include a hole transport layer and a hole injection layer.

The emissive layer EML may be disposed on the hole control layer HCL. The emissive layer EML may be disposed in an area corresponding to the opening PX_OP. The emissive layer EML may include an organic material and/or an inorganic material. The emissive layer EML may generate one of red light, green light, and blue light.

The emissive layer EML may be manufactured by the deposition apparatus illustrated in FIG. 1. A deposition material may be provided on the substrate SUB through the mask openings M-OP of the shadow mask SMK and form the emissive layer EML.

The electron control layer ECL may be disposed on the emissive layer EML and the hole control layer HCL. The electron control layer ECL may be commonly disposed on the emissive portion PA and the non-emissive portion NPA. The electron control layer ECL may include an electron transport layer and an electron injection layer.

The second electrode CE may be disposed on the electron control layer ECL. The second electrode CE may be commonly disposed in the pixels PX.

A thin film encapsulation layer TFE may be disposed on the light emitting element OLED. The thin film encapsulation layer TFE may be disposed on the second electrode CE and may cover the pixel PX. The thin film encapsulation layer TFE may include at least two inorganic layers and an organic layer between the inorganic layers. The inorganic layers may protect the pixel PX from moisture/oxygen. The organic layer may protect the pixel PX from foreign matter such as, for example, dust particles.

The first voltage may be applied to the first electrode AE through the transistor TR, and the second voltage having a lower level than the first voltage may be applied to the second electrode CE. Holes and electrons injected into the emissive layer EML may be combined to form excitons, and as the excitons transition to a ground state, the light emitting element OLED may emit light.

The above-described substrate alignment keys SAK may be formed by being subjected to patterning with the same material as one of the gate electrode G, the first connecting electrode CNE1, and the second connecting electrode CNE2. The substrate alignment keys SAK may be disposed in the same layer as one of the gate electrode G, the first connecting electrode CNE1, and the second connecting electrode CNE2.

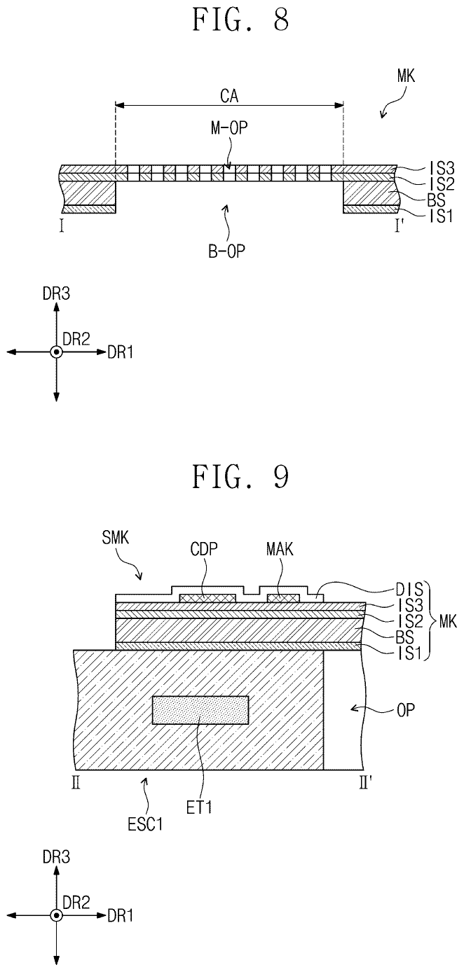

FIG. 8 is a sectional view taken along line I-I′ illustrated in FIG. 3.

Referring to FIGS. 3 and 8, the mask MK may include a base layer BS, a first inorganic layer IS1, a second inorganic layer IS2, and a third inorganic layer IS3. The first inorganic layer IS1 may be disposed under the base layer BS. The second inorganic layer IS2 may be disposed on the base layer BS, and the third inorganic layer IS3 may be disposed on the second inorganic layer IS2. The base layer BS may serve as a support substrate on which the first inorganic layer IS1, the second inorganic layer IS2, and the third inorganic layer IS3 are disposed.

The mask openings M-OP may be defined in the second inorganic layer IS2 and the third inorganic layer IS3 that overlap each of the cell areas CA. The base layer BS and the first inorganic layer IS1 may be disposed so as not to overlap the cell area CA. For example, a base opening B-OP overlapping the cell area CA may be defined in the base layer BS and the first inorganic layer IS1. Accordingly, the base layer BS and the first inorganic layer IS1 may be disposed around the cell area CA so as not to overlap the cell area CA.

The base layer BS may include silicon (Si). The first inorganic layer IS1 and the third inorganic layer IS3 may include silicon nitride (SiNx). The second inorganic layer IS2 may include silicon oxide (SiOx).

FIG. 9 is a sectional view taken along line II-II′ illustrated in FIG. 3.

Referring to FIGS. 3, 8, and 9, the mask MK may be disposed on the first electrostatic chuck ESC1. The first inorganic layer IS1 may be disposed on the first electrostatic chuck ESC1, the base layer BS may be disposed on the first inorganic layer IS1, and the second inorganic layer IS2 and the third inorganic layer IS3 may be disposed on the base layer BS.

The mask alignment keys MAK and the conductive patterns CDP may be disposed on the third inorganic layer IS3. Accordingly, the mask alignment keys MAK and the conductive patterns CDP may be disposed in the same layer.

The mask alignment keys MAK and the conductive patterns CDP may include the same material. Accordingly, the mask alignment keys MAK may include tungsten, aluminum, or magnesium as a paramagnetic material. The mask alignment keys MAK and the conductive patterns CDP may be formed by being simultaneously subjected to patterning with the same material.

The mask MK may further include a dummy inorganic layer DIS disposed on the mask alignment keys MAK and the conductive patterns CDP. The dummy inorganic layer DIS may be disposed on the third inorganic layer IS3 and cover the mask alignment keys MAK and the conductive patterns CDP. The dummy inorganic layer DIS, when viewed from above the plane, may be disposed adjacent to the periphery of the mask MK without overlapping the opening OP. Accordingly, the dummy inorganic layer DIS may be disposed such that the dummy inorganic layer DIS does not overlap the cell areas CA.

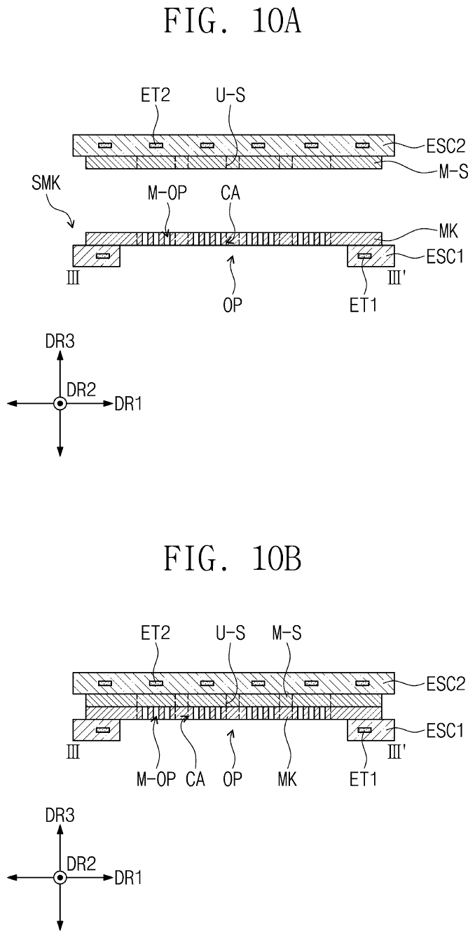

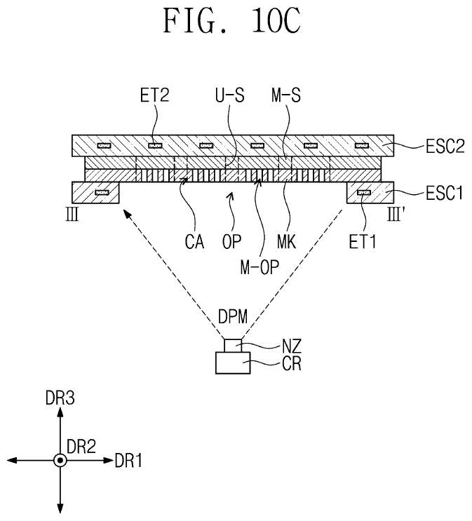

FIGS. 10A to 10C are views for explaining a deposition process of the deposition apparatus.

For example, FIGS. 10A to 10C are sectional views corresponding to the cross-section taken along line III-III′ illustrated in FIG. 3. In some aspects, for convenience of description, the conductive patterns CDP, the substrate alignment keys SAK, and the mask alignment keys MAK are omitted in FIGS. 10A to 10C, and the conductive patterns CDP, the substrate alignment keys SAK, and the mask alignment keys MAK, which are omitted, are referred to by FIGS. 1 to 3.

Referring to FIGS. 1 to 3 and 10A, a voltage may be applied to the first electrodes ET1 of the first electrostatic chuck ESC1, and the mask MK may be attracted and clamped to the upper surface of the first electrostatic chuck ESC1 by an electrostatic force. A voltage may be applied to the second electrodes ET2 of the second electrostatic chuck ESC2, and the mother substrate M-S may be attracted and clamped to the lower surface of the second electrostatic chuck ESC2 by an electrostatic force.

When viewed from above the plane, the substrate alignment keys SAK may be disposed such that the substrate alignment keys SAK overlap the mask alignment keys MAK, and the mother substrate M-S may be aligned in place with the mask MK. In the deposition process, the substrate SUB may be turned upside down such that the transistor TR disposed on the substrate SUB illustrated in FIG. 7 faces downward in FIGS. 1 and 10A. Accordingly, in the deposition process, substantially, the substrate alignment keys SAK may be disposed on the lower surface of the mother substrate M-S to face toward the mask alignment keys MAK.

Referring to FIGS. 1 to 3 and 10B, after the mother substrate M-S is aligned with the mask MK, the second electrostatic chuck ESC2 and the mother substrate M-S may move downward, and the mother substrate M-S may make contact with the mask MK.

Referring to FIGS. 1 to 3 and 10C, the deposition apparatus DPA may include a crucible CR disposed under the first electrostatic chuck ESC1. Although one crucible CR is illustrated as an example, a plurality of crucibles CR may be disposed under the first electrostatic chuck ESC1.

A nozzle NZ may be disposed at the top of the crucible CR. A deposition material DPM may be contained in the crucible CR. Although not illustrated, a heat source for heating the crucible CR may be disposed in the crucible CR. Although not illustrated, the deposition apparatus DPA may be disposed in a vacuum chamber used in a manufacturing process of the display device DD.

The crucible CR may be heated, and the deposition material DPM may be vaporized and jetted upward through the nozzle NZ. The vaporized deposition material DPM may be provided to the mother substrate M-S through the opening OP and the mask openings M-OP. The deposition material DMP may include an organic material for forming the emissive layer EML. The deposition material DPM may be provided on the mother substrate M-S and form the emissive layer EML.

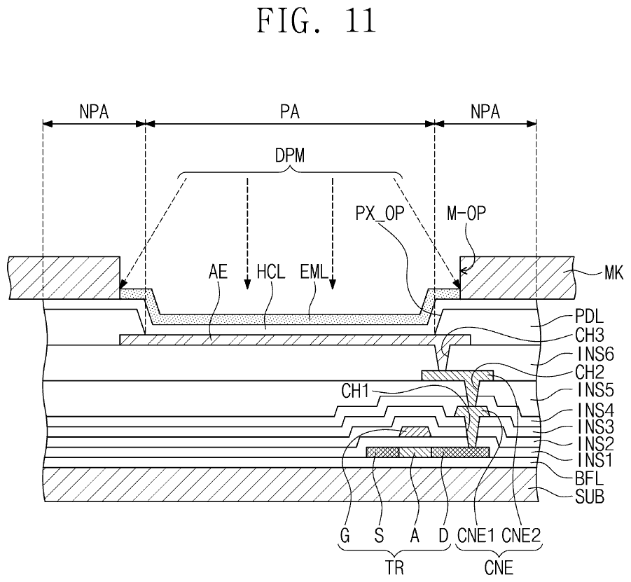

FIG. 11 is a view illustrating a state in which the deposition material is provided on the mother substrate in FIG. 10C.

Referring to FIG. 11, the mask MK may be disposed on the substrate SUB. The substrate SUB may be the mother substrate M-S illustrated in FIG. 10C. For convenience of description, the emissive layer EML is illustrated as facing upward, and the mask MK is illustrated as being disposed on the emissive layer EML. However, substantially, the structure illustrated in FIG. 11 may correspond to an inverted state of FIGS. 10A to 10C in the deposition process. For example, the emissive layer EML may face downward, and the mask MK may be disposed under the emissive layer EML.

The hole control layer HCL may be disposed on the first electrode AE, and embodiments of the present disclosure may include using the mask MK to form the emissive layer EML on the hole control layer HCL. The deposition material DPM may be provided on the hole control layer HCL through the mask opening M-OP defined in the mask MK. The emissive layer EML may be formed by the deposition material DPM. Although one emissive layer EML is formed on the substrate SUB, a plurality of emissive layers EML may be formed on the substrate SUB.

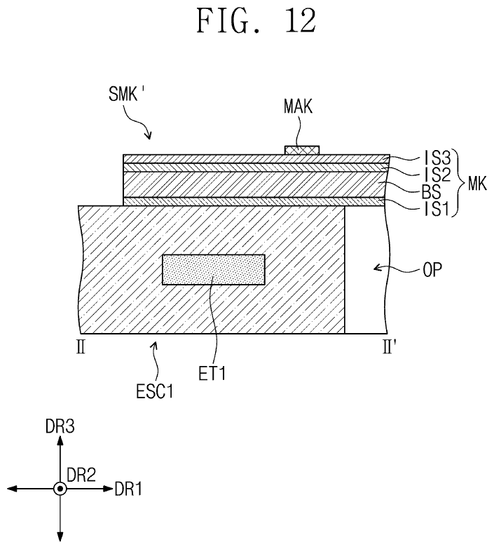

FIG. 12 is a view illustrating a configuration of a comparative shadow mask according to a comparative example.

For example, FIG. 12 is a sectional view corresponding to FIG. 9.

Referring to FIG. 12, the comparative shadow mask SMK′ may not include the conductive patterns CDP. Other components of the comparative shadow mask SMK′ may be substantially the same as the components of the shadow mask SMK.

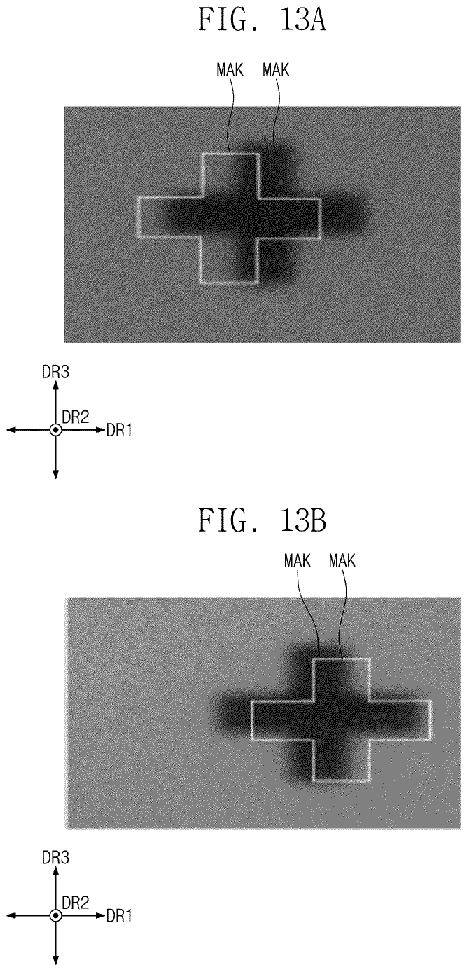

FIGS. 13A and 13B are views obtained by measuring movement states of mask alignment keys when the comparative shadow mask is used in a deposition process.

The mask alignment keys MAK illustrated in FIGS. 13A and 13B may be left and right mask alignment keys MAK spaced apart from each other in the first direction DR1 based on FIG. 3.

Referring to FIGS. 12, 13A, and 13B, black crosses represent the positions of the mask alignment keys MAK in the state in which the comparative shadow mask SMK′ and the mother substrate M-S are aligned with each other in correspondence to the process state illustrated in FIG. 10A. Crosses illustrated by white lines represent the positions of the mask alignment keys MAK in the state in which the comparative shadow mask SMK′ and the mother substrate M-S are in contact with each other in correspondence to the process state illustrated in FIG. 10B.

Referring to FIGS. 10A, 10B, 12, 13A, and 13B, the crosses illustrated by the white lines may be moved leftward and rightward, respectively, relative to the black crosses. That is, unlike in the state in which the comparative shadow mask SMK′ and the mother substrate M-S are aligned with each other, the positions of the mask alignment keys MAK may be moved leftward and rightward in the state in which the comparative shadow mask SMK′ and the mother substrate M-S are in contact with each other.

Since the comparative shadow mask SMK′ does not include the conductive patterns CDP, the Coulomb force on the first electrostatic chuck ESC1 and the comparative shadow mask SMK′ may be weak when an electrostatic force is generated from the first electrostatic chuck ESC1. Accordingly, the attraction force (or, the clamping force) of the first electrostatic chuck ESC1 for the comparative shadow mask SMK′ may be weak.

When the mother substrate M-S makes contact with the comparative shadow mask SMK′ in the process illustrated in FIG. 10B, a certain pressure may be applied to the comparative shadow mask SMK′. The position of the comparative shadow mask SMK′ may be misaligned with the correct position due to the pressure. Since the attraction force of the first electrostatic chuck ESC1 for the comparative shadow mask SMK′ is weak, the position of the comparative shadow mask SMK′ may be more significantly misaligned with the correct position.

Accordingly, when the comparative shadow mask SMK′ is used, the displacement of the mask alignment keys MAK may increase. In the comparative shadow mask SMK′, the displacement of the mask alignment keys MAK in the first direction DR1 was measured to be 7.39 micrometers (μm).

Since the comparative shadow mask SMK′ is significantly misaligned with the correct position, the emissive layers EML of the pixels PX may more significantly deviate from the correct positions. As a result, a defective display panel may be formed, and therefore the yield of the display device DD may be lowered.

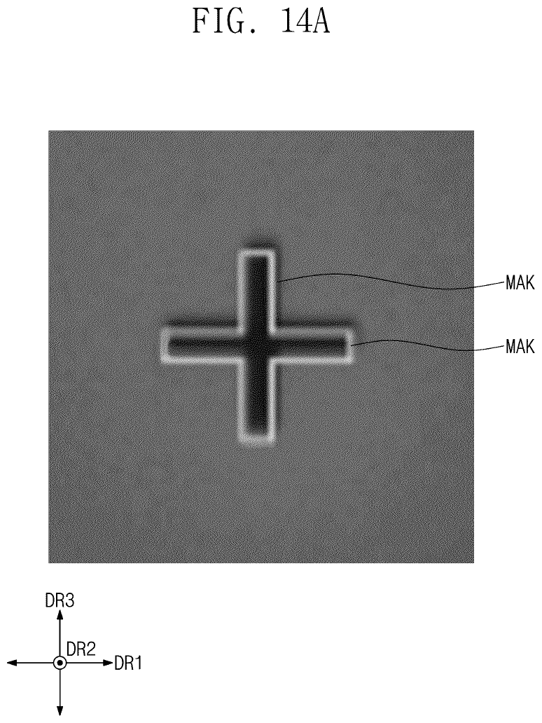

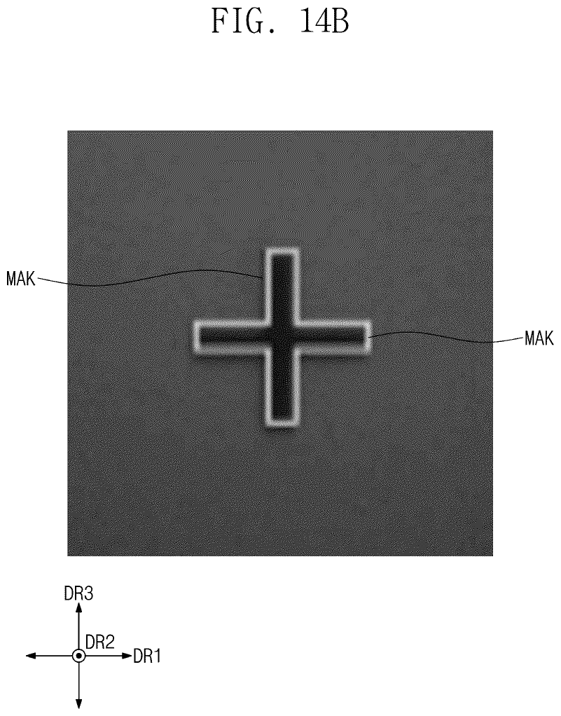

FIGS. 14A and 14B are views obtained by measuring movement states of mask alignment keys when a shadow mask according to an embodiment of the present disclosure is used in a deposition process.

The mask alignment keys MAK illustrated in FIGS. 14A and 14B may be left and right mask alignment keys MAK spaced apart from each other in the first direction DR1 based on FIG. 3.

Referring to FIGS. 9, 10A, 14A, and 14B, black crosses represent the positions of the mask alignment keys MAK in the state in which the shadow mask SMK and the mother substrate M-S are aligned with each other.

Referring to FIGS. 9, 10B, 14A, and 14B, crosses illustrated by white lines represent the positions of the mask alignment keys MAK in the state in which the shadow mask SMK and the mother substrate M-S are in contact with each other.

Referring to FIGS. 9, 10A, 10B, 14A, and 14B, since the shadow mask SMK according to an embodiment of the present disclosure includes the conductive patterns CDP, the Coulomb force on the first electrodes ET1 of the first electrostatic chuck ESC1 and the shadow mask SMK may be strengthened when an electrostatic force is generated from the first electrostatic chuck ESC1. Accordingly, the attraction force (or, the clamping force) of the first electrostatic chuck ESC1 for the shadow mask SMK may be strengthened. As a result, the shadow mask SMK may be more firmly clamped to the first electrostatic chuck ESC1.

When the mother substrate M-S makes contact with the shadow mask SMK in FIG. 10B, a certain pressure may be applied to the shadow mask SMK. Since the attraction force of the first electrostatic chuck ESC1 for the shadow mask SMK is strong, the shadow mask SMK may not be significantly misaligned with the correct position. That is, the shadow mask SMK may be more accurately maintained in the correct position.

Accordingly, the displacement of the mask alignment keys MAK may decrease. In the shadow mask SMK, the displacement of the mask alignment keys MAK in the first direction DR1 was measured to be 0.10 micrometers (μm).

In an embodiment of the present disclosure, even though a certain pressure is applied to the shadow mask SMK, the position of the shadow mask SMK may not be significantly changed and may be maintained in the correct position. Accordingly, the emissive layers EML of the pixels PX may be more accurately formed in the correct positions. As a result, the display panel DP may be normally formed, and thus the yield of the display device DD may be improved.

According to the embodiments of the present disclosure, the shadow mask may include the mask and the conductive patterns disposed on the mask, and the conductive patterns may overlap the electrodes of the electrostatic chuck disposed under the mask. The Coulomb force on the electrodes of the electrostatic chuck and the conductive patterns may be formed to be stronger, and thus the shadow mask may be more firmly clamped to the electrostatic chuck when the electrostatic force is generated by the electrodes of the electrostatic chuck.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A deposition apparatus comprising:
a first electrostatic chuck in which an opening is defined and comprising a plurality of first electrodes:
a second electrostatic chuck disposed over the first electrostatic chuck, the second electrostatic chuck comprising a lower surface to which a substrate is attracted; and
a shadow mask disposed between the first electrostatic chuck and the second electrostatic chuck, the shadow mask comprising a mask attracted to an upper surface of the first electrostatic chuck and a plurality of conductive patterns disposed on the mask,
wherein the plurality of conductive patterns overlap the plurality of first electrodes when viewed on a plane.

2. The deposition apparatus of claim 1, wherein the plurality of conductive patterns comprise a paramagnetic material.

3. The deposition apparatus of claim 1, wherein the plurality of conductive patterns comprise tungsten, aluminum, or magnesium.

4. The deposition apparatus of claim 1, wherein the shadow mask further comprises a plurality of mask alignment keys disposed on the mask.

5. The deposition apparatus of claim 4, wherein the plurality of conductive patterns and the plurality of mask alignment keys are disposed in a same layer and comprise a same material.

6. The deposition apparatus of claim 4, wherein the plurality of conductive patterns and the plurality of mask alignment keys are formed by being simultaneously subjected to patterning with a same material.

7. The deposition apparatus of claim 4, wherein the plurality of mask alignment keys are disposed inward of the plurality of conductive patterns.

8. The deposition apparatus of claim 4, wherein the plurality of conductive patterns and the plurality of mask alignment keys do not overlap the opening when viewed on the plane.

9. The deposition apparatus of claim 1, wherein the plurality of conductive patterns are adjacent to a periphery of the mask.

10. The deposition apparatus of claim 1, wherein:
the mask comprises:
a base layer;
a first inorganic layer disposed under the base layer;
a second inorganic layer disposed on the base layer; and
a third inorganic layer disposed on the second inorganic layer, and the plurality of conductive patterns are disposed on the third inorganic layer.

11. The deposition apparatus of claim 10, wherein the mask further comprises a dummy inorganic layer disposed on the plurality of conductive patterns.

12. The deposition apparatus of claim 11, wherein:
when viewed on the plane, a planar area of the mask comprises a plurality of cell areas which overlap the opening, and
a plurality of mask openings are defined in the second inorganic layer and the third inorganic layer and overlap each of the plurality of cell areas.

13. The deposition apparatus of claim 12, wherein a base opening which overlaps each of the plurality of cell areas is defined in each of the base layer and the first inorganic layer.

14. The deposition apparatus of claim 10, wherein:
the base layer comprises silicon,
the first inorganic layer and the third inorganic layer comprise silicon nitride, and
the second inorganic layer comprises silicon oxide.

15. The deposition apparatus of claim 1, wherein the second electrostatic chuck comprises a plurality of second electrodes.

16. A deposition apparatus comprising:
a first electrostatic chuck in which an opening is defined and comprising a plurality of first electrodes:
a second electrostatic chuck disposed over the first electrostatic chuck, the second electrostatic chuck comprising a lower surface to which a substrate is attracted; and
a shadow mask disposed between the first electrostatic chuck and the second electrostatic chuck,
wherein:
the shadow mask comprises:
a mask attracted to an upper surface of the first electrostatic chuck;
a plurality of conductive patterns disposed on the mask; and
a plurality of mask alignment keys disposed on the mask, and
the plurality of mask alignment keys are disposed inward of the plurality of conductive patterns when viewed on a plane.

17. The deposition apparatus of claim 16, wherein the plurality of conductive patterns overlap the plurality of first electrodes when viewed on the plane.

18. The deposition apparatus of claim 16, wherein the plurality of conductive patterns comprise a paramagnetic material.

19. The deposition apparatus of claim 16, wherein the plurality of conductive patterns and the plurality of mask alignment keys are formed by being simultaneously subjected to patterning with a same material.

20. An electronic device comprising:
a display device;
an electro-optical module disposed under the display device and which receives an optical signal through a first transmissive area of the display device; and
a casing which accommodates the display device and the electro-optical module,
wherein the display device comprises:
a display panel in which the first transmissive area is defined, the display panel being manufactured by a shadow mask comprising:
a mask in which a plurality of mask openings are defined,
a plurality of conductive patterns disposed on the mask, and
a plurality of mask alignment keys disposed inward of the plurality of conductive patterns on the mask; and
a window disposed on the display panel.
